(19) United States
(12) Patent Application Publication
(10) Pub. No.: US 2013/0285524 A1
(43) Pub. Date: Oct. 31, 2013

(54) HOUSING WITH INTEGRAL PROTECTIVE COVER AND VOLUME KEY

(71) Applicants: ZHENG SHI, Shenzhen City (CN); JIANG-FENG LIU, Shenzhen City (CN); TIAN XU, Shenzhen City (CN)

(72) Inventors: ZHENG SHI, Shenzhen City (CN); JIANG-FENG LIU, Shenzhen City (CN); TIAN XU, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/600,571

(22) Filed: Aug. 31, 2012

(30) Foreign Application Priority Data
Apr. 26, 2012 (CN) 201210125651.4

(51) Int. Cl. H05K 5/03; H05K 5/02

(52) U.S. Cl. 312/293.3; 312/223.1

(57) ABSTRACT

A housing includes a main body and an outside layer. The main body defines an opening. The outside layer is bonded by molding to the main body. The outside layer and the main body includes different materials. The outside layer includes a protective cover. One end of the protective cover is bent relative to the main body, and another end of the protective cover is releasably latched in the main body for selectively covering or exposing the opening

### BACKGROUND

1. Technical Field

The present disclosure relates to a housing that includes an integral protective cover and a volume key.

2. Description of Related Art

With the development of wireless communication and information processing technologies, portable electronic devices such as mobile phones are now widely used. Surface contact cards and volume keys are necessary elements in portable electronic devices. Conventional housings of the portable electronic device define an opening for insertion and removal of the surface contact card, and has a separable protective cover covering the opening. The protective cover is usually manufactured independently. Similarly, the volume keys are also manufactured independently. This structure complicates the assembly process.

Therefore, there is room for improvement within the art.

### BRIEF DESCRIPTION OF THE DRAWINGS

Many aspects of the present housing for making the same can be better understood with reference to the following drawings. The components in the various drawings are not necessarily drawn to scale, the emphasis instead being placed upon clearly illustrating the principles of the present disclosure. Moreover, in the drawings, like reference numerals designate corresponding parts throughout the diagrams.

FIG. 1 is a sectional schematic view of a main body of a housing according to an exemplary embodiment.

FIG. 2 is a sectional schematic view of the housing in FIG. 1 with an outside layer.

### DETAILED DESCRIPTION

The disclosed molded article can be a housing of electronic device, such as a mobile phone or personal digital assistant.

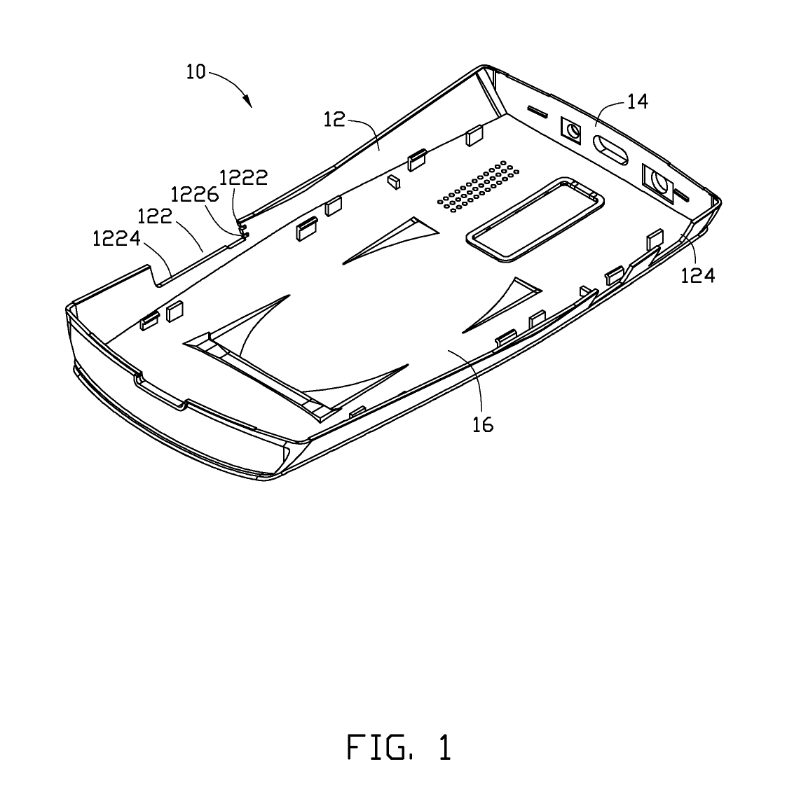

FIG. 1 shows a housing 100 according to an exemplary embodiment. The housing 100 includes a main body 10 and an outside layer 20 bonded by molding to the main body 10.

The main body 10 includes two opposite first sidewalls 12, two opposite second sidewalls 14, and a bottom wall 16 connected to the first sidewalls 12 and the second sidewalls 14. One of the first sidewalls 14 defines an opening 122 for allowing a surface contact card to be inserted into or removed therefrom. The opening 122 is surrounded by two opposite first edges 1222 and a second edge 1224 connected the first edges 1222. One of the first edges 1222 defines a plurality of latching grooves 1226. The other of the first sidewalls 14 defines at least one volume notch 124 for allowing operation of a volume switch. In this exemplary embodiment, the main body 10 includes hard material such as a plastic material selected from a group including polycarbonate (PC), acrylonitrile-butadiene-styrene (ABS). The hard material for the main body 10 adds mechanical strength. In addition, ABS and PC exhibit good adhesion to many softer materials.

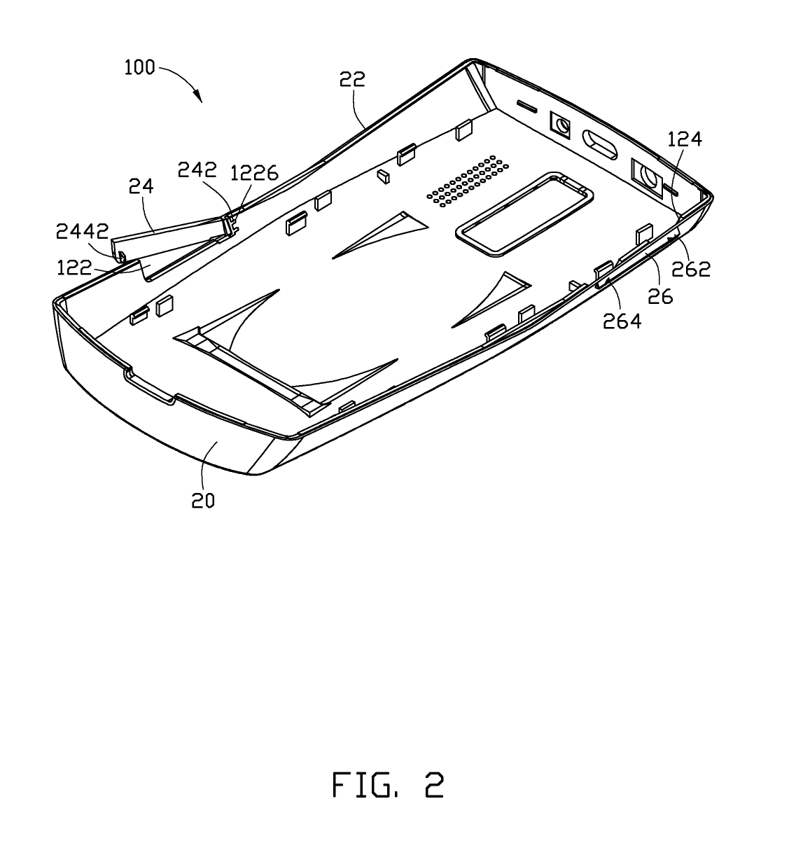

Referring to FIG. 2, the outside layer 20 includes a soft material for covering the main body 10. The main body 10 and the outside layer 20 are fabricated by dual-injection molding. In this exemplary embodiment, the outside layer 20 includes thermoplastic polyurethanes (TPU). The outside layer 20 includes a main section 22, a protective cover 24, and a volume key 26. The main section 22 is bonded by molding to the main body 10. The protective cover 24 is flexibly connected to the main body 10 for selectively covering or exposing the opening 122. One end of the protective cover 24 includes a plurality of latching portions 242. The latching portions 242 are embedded in the latching grooves 1226 during dual-injection molding. Another end of the protective cover 24 has a clasp 2442 configured for being latched in the first edge 1222 of the opening 122 far away from the latching grooves 1226. The volume key 26 is flexibly connected to the main body 10, and covers the notch 124. In this exemplary embodiment, the volume key 26 includes a first end 262 and a second end 264 for adjusting the volume of the portable electronic device.

To fabricate the housing 100, a plastic molding material is injected into a chamber of a mold apparatus to form the main body 10. Then, a second molding material is injected into the chamber, and integrally combines the main body to form the housing 100. The second molding material forms the outside layer 20. The outside layer 20 encloses the main body 10 and fills in the opening 122 and the notch 124 to correspondingly form the protective cover 24 and the volume key 26. Since the protective cover 24 includes soft material, the protective cover 24 has a large elasticity allowing the protective cover 24 to bend relative to the main body 10 for selectively covering or exposing the opening 122. Similarly, the volume key 26 can be elastically pressed to operate the volume key 26.

It is to be understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. A housing comprising:
a main body defining an opening;
an outside layer moldingly bonded to the main body, the main body and the outside layer made of different materials; the outside layer including a protective cover;
wherein one end of the protective cover is bent relative to the main body, and another end of the protective cover is releasably latched in the main body for selectively covering or exposing the opening.

2. The housing as claimed in claim 1, wherein the main body defines at least one notch, the outside layer includes a volume key attached to the at least one notch.

3. The housing as claimed in claim 1, wherein the main body comprises polycarbonate or acrylonitrile-butadiene-styrene, and the outside layer comprises thermoplastic polyurethanes.

4. The housing as claimed in claim 1, wherein the opening is surrounded by two opposite first edges and a second edge connected the first edges, one of the first edge defines a plurality of latching grooves, one end of the protective cover includes a plurality of latching portions embedded in the latching grooves.

5. The housing as claimed in claim 4, wherein another end of the protective cover has a clasp configured for being latched in the first edge of the opening far away from the latching grooves.

6. A housing comprising:
a main body comprising a first material and defining an opening and at least one notch;
a protective cover and a volume key moldingly bonded to the main body, the protective cover and the volume key made of a second material different from the first material;
wherein the protective cover is bent relative to the main body for selectively covering or exposing the opening, and the volume key is elastically pressed in the notch.

7. The housing as claimed in claim 6, wherein the main body comprises polycarbonate or acrylonitrile-butadiene-styrene, and the protective cover and the volume key comprise thermoplastic polyurethanes.

8. The housing as claimed in claim 6, wherein the opening is surrounded by two opposite first edges and a second edge connected the first edges, one of the first edge defines a plurality of latching grooves, one end of the protective cover includes a plurality of latching portions embedded in the latching grooves.

9. The housing as claimed in claim 8, wherein another end of the protective cover has a clasp configured for being latched in the first edge of the opening far away from the latching grooves.
